(19) United States
(12) Patent Application Publication
(10) Pub. No.: US 2002/0023775 A1
(43) Pub. Date: Feb. 28, 2002

(54) Sequentially processed circuitry

(76) Inventors: Per Ligander, Goteborg (SE); Leif Bergstedt, Sjomarken (SE)

Correspondence Address: Ronald L. Grudziecki, BURNS, DOANE, SWECKER & MATHIS, L.L.P., P.O. Box 1404, Alexandria, VA, 22313-1404, US

(21) Appl. No.: 09/943,203

(22) Filed: Aug. 30, 2001

(30) Foreign Application Priority Data
Aug. 31, 2000 (SE) 0003085-8

(51) Int. Cl. H05K 1/03

(52) U.S. Cl. 174/255; 174/259

(57) ABSTRACT

An encapsulated circuit board arrangement comprising a thin interface layer with one or more vias for input/output interface to the circuit. The encapsulated circuit board arrangement further comprises one or more sequentially processed layers added to one side of the interface circuit. The sequentially processed layers are preferably made by additive offset printing technology. The encapsulated circuit board arrangement further comprises a layer of adhesive. A first side of the adhesive layer is attached on top of the uppermost and most exposed layer. The encapsulated circuit board arrangement further comprises a support carrier attached on a second side of the adhesive layer.

### TECHNICAL FIELD

The invention concerns sequentially processed circuitry.

### BACKGROUND

Traditionally printed circuit boards have been manufactured by one of two basic techniques. The first technique begins with a copper (or other conductive material) coated substrate and selectively removes the conductive material in accordance with a photo defined masking and etching process defined pattern and chemical etch. The second basic method utilizes the addition of conductive material by way of photodefined patterns to provide properly interconnected conductors. In the construction of a sequentially processed multilayer printed wiring board, as opposed to a laminated multilayer board, each dielectric/conductor layer is applied by a sequence of processes which construct, first, the dielectric, then the vias or interlayer interconnection, then the conductors. Such processes use a combination of addition and etching of metals as well as addition and removal of applied dielectric to obtain both the conductors and the dielectric with conductive holes (vias) which connect conductors on one layer with conductors above and below.

These processes and a further development of these processes are described in U.S. Pat. No. 5,260,170. However it can be considered a disadvantage to use these processes as the most sensitive tracks are left unprotected on top, i.e. there is a need for a method of manufacturing sequentially processed circuit board arrangement which do not leave sensitive tracks and other circuitry unprotected.

### SUMMARY

An object of the invention is to define a sequentially processed circuit board arrangement which does not leave sensitive circuit patterns unprotected and also to define a method of manufacturing the same.

Another object of the invention is to define an encapsulation of sequentially processed tracks and circuit patterns of extremely thin layers of environmentally less resistant materials, such as less stable polymers, for example dielectric of thin layers of acrylate.

A further object of the invention is to define a sequentially processed circuit board arrangement with improved cooling of the circuit.

The aforementioned objects are achieved according to the invention by an encapsulated circuit board arrangement comprising a thin interface layer with possibly one or more vias for input/output interface to the circuit patterns. The encapsulated circuit board arrangement further comprises one or more sequentially processed circuit layers added to one side of the interface layer. The sequentially processed circuit layers are preferably made by additive offset printing technology. The encapsulated circuit board arrangement further comprises a layer of adhesive. A first side of the adhesive layer is attached on top of the uppermost and most exposed circuitry layer. The encapsulated circuit board arrangement further comprises a support carrier attached on a second side of the adhesive layer.

The aforementioned objects are also achieved according to the invention by a process for the formation of an encapsulated circuit board arrangement having at least one layer of sequentially processed tracks. The encapsulated circuit board arrangement has a first side as an interface side and a second side as a protective cover. According to the invention the process comprises a plurality of steps. In a first step applying at least one layer of sequentially processed tracks on a first side of an interface carrier, a second side of the interface carrier being the interface side of the encapsulated circuit board arrangement. Active and passive components, such as surface mount components, can suitably be attached both physically and electrically to the second side of the interface carrier. In a second step joining the last applied sequentially processed layer to a support carrier by means of an adhesive layer, the support carrier forming the protective cover of the second side of the encapsulated circuit board arrangement.

The process preferably either further comprises the step of applying the adhesive layer on top of the last applied sequentially processed layer, or the step of applying the adhesive layer to the support carrier.

Preferably the application of at least one of the at least one sequentially processed layers is by means of offset printing technology. Suitably a dielectric of at least one of the at least one sequentially processed layer is acrylate. Additionally, the application of the adhesive layer is preferably by means of offset printing technology.

The support carrier can in some processes be at least a part of a cover housing in which the encapsulated circuit board arrangement is mounted. In some processes the support carrier is at least a part of an enclosure on which the encapsulated circuit board arrangement is mounted. In some processes the support carrier is rigid, in other processes the support carrier is bendable.

Preferably at least one of the at least one sequentially processed layer comprises connection circuitry. In some processe at least one of the at least one sequentially processed layer comprises tracks arranged as at least one passive component. In some processes at least one of the at least one sequentially processed layer comprises tracks arranged as at least one active component.

Advantageously the interface carrier comprises at least one via, the at least one of the at least one via is preferably solid. In some processes the interface carrier is bendable. The interface carrier is preferably made of polymide or polyester.

The aforementioned objects are also achieved according to the invention by an encapsulated circuit board arrangement having at least one sequentially processed layer. The encapsulated circuit board arrangement has a first side as an interface side and a second side as a protective cover. According to the invention the arrangement comprises a plurality of sequentially processed layers. The arrangement comprises an interface layer having a first side and a second side, the first side of the interface layer being the interface side of the encapsulated circuit board arrangement. Active and passive components, such as surface mount components, can suitably be attached both physically and electrically to the first side of the interface carrier. The arrangement further comprises at least one layer of sequentially processed tracks on the second side of the interface layer. The arrangement also comprises a support layer forming the protective cover of the second side of the encapsulated circuit board arrangement. Finally the arrangement also comprises an adhesive layer between a top of the last sequentially processed layer and the support carrier.

Advantageously at least one of the at least one sequentially processed layer has been added by means of offset printing technology and suitably a dielectric of at least one of the at least one sequentially processed layer is acrylate. In some embodiments the adhesive layer has preferably been added by means of offset printing technology.

The support layer can is some embodiments be at least a part of a cover housing in which the encapsulated circuit board arrangement is mounted. In some embodiments the support carrier is at least a part of an enclosure on which the encapsulated circuit board arrangement is mounted. In some embodiments the support layer is rigid in other embodiments the support layer is bendable.

Advantageously at least one of the at least one sequentially processed layer comprises connection circuitry. In some embodiments at least one of the at least one sequentially processed layer comprises tracks arranged as at least one passive component. In some embodiments at least one of the at least one sequentially processed layer comprises tracks arranged as at least one active component.

The interface layer preferably comprises at least one via and preferably at least one of the at least one via is solid. In some embodiments the interface layer is bendable and preferably made of polymide or polyester.

The aforementioned objects are also achieved according to the invention by a device comprising wireless communication means, which device comprises an encapsulated circuit board arrangement according to any above described encapsulated circuit board arrangements according to the invention or encapsulated circuit board arrangement made according to any above described process according to the invention.

The aforementioned objects are also achieved according to the invention by a wireless or wireless mobile terminal which comprises an encapsulated circuit board arrangement according to any above described encapsulated circuit board arrangement according to the invention for wireless communication.

By providing an encapsulated circuit board arrangement according to the invention a plurality of advantages over prior art circuit boards are obtained. Primary purposes of the invention are to provide a well protected and well cooled circuit board arrangement by cheap manufacturing methods. Other advantages of this invention will become apparent from the detailed description.

### BRIEF DESCRIPTION OF THE DRAWINGS

The invention will now be described in more detail for explanatory, and in no sense limiting, purposes, with reference to the following figures, in which

FIGS. 1a-1e shows a cross section of sequentially processed circuit board arrangement according to the invention during different processing steps.

### DETAILED DESCRIPTION

Encapsulation of printed circuits, with or without active and/or passive cuircuitry, that are processed sequentially is necessary to prevent destruction of the circuit patterns, especially if they are made of environmentally sensitive materials and/or with very thin layers. There is a desire to reduce conductors of a circuit board to less than 5 μm thick and less than 20 μm wide. This has raised an interest in using less stable polymers such as acrylat as thin layers of dielectric. It has been proposed to use offset printing for manufacturing printed circuit boards and also for manufacture of active and passive components, such as transistor functions, resistors, capacitors, sensors, and emitters, with the same process by means of arranging tracks of conductive and semi conductive polymers. The process used is of an additive type. Using offset printing technology will enable manufacturing of surfaces in the order of 450 mm by 600 mm for a multiple of products with sizes in the range of approximately 100 mm by 150 mm to 10 mm by 10 mm. The finished products are unfortunately extremely sensitve to external physical contact. According to the invention, sequentially processed layers are built on an interface carrier. Thereafter a layer of adhesive is added to cover the sequentially processed layers and then a support carrier is stuck onto the adhesive. Alternatively a layer of adhesive is added to a support carrier after which the interface carrier is stuck to the support carrier with the sequentially processed layers closest to the adhesive on the support carrier. A sandwich construction is thus attained with the interface carrier on one side and the support carrier on the other side protecting the fragile layers within.

As an example, a temperature log of a frozen merchandize is desired. An appropriate circuit layout is manufactured on an interface carrier of at least semi-transparent polyester. The circuit side is joined by an adhesive with a cardboard box in which the frozen merchandize is to be transported. The cardboard box of the frozen merchanize will then function as the support carrier. The circuit with appropriate arranged tracks as sensors is mounted directly onto the object to be monitored and a readout of conditions can be made through the interface carrier by means of appropriate tracks arranged as light emitting diodes. The adhesive layer between the carboard box, the support carrier, and the circuit can be shaped such that sensors or electrical contacts are not covered but have a direct contact with the support carrier, while at the same time providing a sufficient seal.

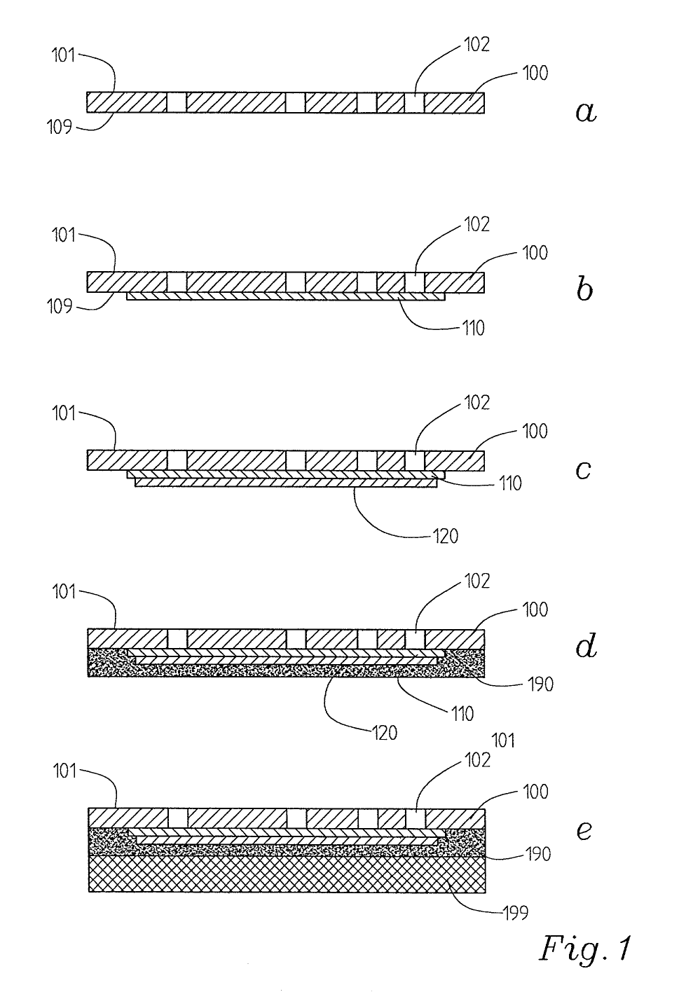

In order to clarify the method and device according to the invention, some examples of its use will now be described in connection with FIGS. 1a to 1e. FIGS. 1a to 1e shows a cross section of sequentially processed circuit board arrangement according to the invention during different processing steps.

In a first step, as is shown in FIG. 1a, the manufacturing starts with an interface carrier 100. The interface carrier 100 is preferably made of a flexible or semi-flexible material such as polymide or polyester, suitably in the range of 25 μm thick. In some embodiments the interface layer, only or in addition, provides an optical interface to underlying sequentially processed circuitry by being at least semi transparent. The underlying sequentially processed circuit layout might comprise tracks arranged as light emitting diodes that are used for a visual readout on a first side 101 of the interface layer. The first side 101 of the interface layer can also be arranged for possible external electrical connections to suitable parts of the sequentially processed circuitry by means of optional via holes 102 such as micro vias and other suitable circuitry such as copper conductors up to approximately 35 μm thick. The optional via holes 102 provide for electrical interconnections between the first side 101 and a second side 109 of the interface carrier 100. The vias 102 are preferably solid vias to provide cooling of sequentially processed circuitry on the second side 109. The vias 102 and any other electrical circuitry are preferably preprocessed. The first side 101 of the interface layer is where passive or active components, such as surface mount components, are arranged, with electrical contact with the tracks of the sequentially processed layers by means of the vias 102. The second side 109 of the interface carrier 100 is the manufacturing support for the sequentially processed layers and will also provide any possible electrical connections to it. Preferably an area of the interface carrier 100 is larger than any area of a sequentially processed layer.

In a second step, as is shown in FIG. 1b, a first sequentially processed circuitry layer 110 is manufactured onto the second side 109 of the interface carrier 100. The layers of tracks are suitably added by offset printing technology. The layers are just electrical interconnection circuitry, which can be also be arranged as passive or, with the help of semi-conducting tracks, active components. FIG. 1c shows a second sequentially processed layer 120 being added. A printed circuit board arrangement according to the invention comprises at least one track layer 110, preferably at least two layers 110, 120. The process of adding sequentially processed layers is repeated as many times as desired. When all the layers 110, 120 have been added to the second side 109 of the interface carrier 100, then, as shown in FIG. 1d, an adhesive layer 190 is added on top of the last added layer, in this example the second layer 120. The adhesive layer 190 is preferably also applied with offset printing techniques. The adhesive layer 190 will seal the sequentially processed layers 110, 120. The adhesive layer 190 may suitably be fluid epoxy added by roller coating. In some embodiments according to the invention the adhesive layer is first added to a support carrier. The adhesive layer 190 may be formed such that it only covers the sequentially processed layers 110, 120, or extends beyond the sequentially processed layers 110, 120, i.e. an area of the adhesive layer 190 is larger than an area of the largest sequentially processed layer. The adhesive layer can preferably be of substantially a same area as the interface carrier 100, but in some embodiments it can be larger and in other embodiments it will be smaller. The adhesive layer 190 will preferably seal the sequentially processed layers 110, 120. In some embodiments the adhesive layer 190 may comprise apertures for, for example, connections, electrical or other, to a support carrier.

In a final step, as shown in FIG. 1e, a support carrier 199 is stuck onto the adhesive layer 190. Or alternatively a carrier with an adhesive layer is stuck onto the sequentially processed layers. The support carrier 199 will typically be in the order of millimeters to approximately 200 μm thick. The main purpose of the support carrier 199 is to provide a physical barrier and protection to the sensitive sequentially processed layers 110, 120. The support carrier 199 can, for example, be of paper, plastic or metal, be bendable or rigid, be a part of a chassi or cover/case/housing of an apparatus in which the circuit board arrangement is mounted, or be a carrier/box onto which the circuit board arrangement is mounted. As an example, the casing might be of a mobil phone or an accessory to it, such as a blue tooth accessory, in which case the total electronic circuitry, with or without active or passive components, will take very little space and still be very well protected. If the support carrier 199 is a part of a casing, then most likely it will not be plane. The support carrier 190 may also comprise apertures, then preferably aligned with any apertures in the adhesive layer 190, for electrical access or access to any sensor on the outermost sequentially processed layer 120.

The basic principle of the invention is to manufacture a plurality of extremely thin and vunerable sequentially processed track layers on an interface carrier, turn the whole thing over and join an uppermost and most exposed layer with a support carrier by means of a layer of adhesive that is either added to the uppermost layer or the support carrier. The interface carrier, onto which the layers have been added, will provide a communication interface to the circuitry, and in most applications be where passive and active conventional components, most preferably surface mount, will be added.

The invention is not restricted to the above described embodiments, but may be varied within the scope of the following claims.

FIG. 1

100 an interface carrier,

101 a first side of the interface carrier for external connections,

102 via holes such as micro vias for electrical interconnections between the first and a second side of the interface carrier,

109 the second side of the interface carrier for layers of tracks and connections to these,

110 a first sequentially processed layer,

120 a second sequentially processed layer,

190 an adhesive layer,

199 a support carrier.

1. A process of forming an encapsulated circuit board arrangement having at least one layer of tracks, the encapsulated circuit board arrangement having a first side as an interface side and a second side as a protective cover, wherein the process comprises the steps of:
applying at least one layer of sequentially processed tracks on a first side of an interface carrier, a second side of the interface carrier being the interface side of the encapsulated circuit board arrangement,
joining the last applied sequentially processed layer to a support carrier by means of an adhesive layer, the support carrier forming the protective cover of the second side of the encapsulated circuit board arrangement.

2. The process according to claim 1, wherein the process further comprises the step of:
applying the adhesive layer on top of the last applied sequentially processed layer.

3. The process according to claim 1, wherein the process further comprises the step of:
applying the adhesive layer to the support carrier.

4. The process according to any one of claims 1 to 3, wherein the application of at least one of the at least one sequentially processed layer is by means of offset printing technology.

5. The process according to claim 4, wherein the step of applying at least one layer of sequentially processed tracks comprises applying an acrylate as a dielectric of at least one of the at least one sequentially processed layer.

6. The process according to any one of claims 2 or 3, wherein the application of the adhesive layer is by means of offset printing technology.

7. The process according to claim 1, wherein the step of joining the last applied sequentially processed layer to a support carrier comprises joining the last applied sequentially processed layer to a support carrier which is at least a part of a cover housing in which the encapsulated circuit board arrangement is mounted.

8. The process according to claim 1, wherein the step of joining the last applied sequentially processed layer to a support carrier comprises joining the last applied sequentially processed layer to a support carrier which is at least a part of an enclosure on which the encapsulated circuit board arrangement is mounted.

9. The process according to claim 1, wherein the step of joining the last applied sequentially processed layer to a support carrier comprises joining the last applied sequentially processed layer to a support carrier which is rigid.

10. The process according to claim 1, wherein the step of joining the last applied sequentially processed layer to a support carrier comprises joining the last applied sequentially processed layer to a support carrier which is bendable.

11. The process according to claim 1, wherein the step of applying at least one layer of sequentially processed tracks comprises applying at least one sequentially processed layer comprising connection circuitry.

12. The process according to any one of claims 1 or 11, wherein the step of applying at least one layer of sequentially processed tracks comprises applying at least one sequentially processed layer comprising tracks arranged as at least one passive component.

13. The process according to any one of claims 1, 11 or 12, wherein the step of applying at least one layer of sequentially processed tracks comprises applying at least one sequentially processed layer comprising tracks arranged as at least one active component.

14. The process according to claim 1, wherein the step of applying at least one layer of sequentially processed tracks comprises applying the at least one layer to an interface layer comprising at least one via.

15. The process according to claim 1, wherein the step of applying at least one layer of sequentially processed tracks comprises applying the at least one layer to an interface layer comprising at least one solid via.

16. The process according to any one of claims 1, 14 or 15, wherein the step of applying at least one layer of sequentially processed tracks comprises applying the at least one layer to an interface layer which is bendable.

17. The process according to any one of claims 1 or 16, wherein the step of applying at least one layer of sequentially processed tracks comprises applying the at least one layer to an interface layer which is made of polymide.

18. A device comprising wireless communication means, wherein the device comprises an encapsulated circuit board arrangement made according any one of claims 1 to 17.

19. A wireless mobile terminal, wherein the terminal comprises an encapsulated circuit board arrangement made according any one of claims 1 to 17.

20. An encapsulated circuit board arrangement having at least one sequentially processed track layer, the encapsulated circuit board arrangement having a first side as an interface side and a second side as a protective cover, wherein the circuit board arrangement comprises:
an interface layer having a first side and a second side, a first side of the interface layer being the interface side of the encapsulated circuit,
at least one layer of sequentially processed trackson the second side of the interface carrier,
a support carrier forming the protective cover of the second side of the encapsulated circuit board arrangement,
an adhesive layer between a top of the last sequentially processed layer and the support carrier.

21. The circuit board arrangement according to claim 20, wherein at least one of the at least one sequentially processed layer has been added by means of offset printing technology.

22. The circuit board arrangement according to claim 21, wherein a dielectric of at least one of the at least one sequentially processed layer is acrylate.

23. The circuit board arrangement according to any one of claims 20 to 22, wherein the adhesive layer has been added by means of offset printing technology.

24. The circuit board arrangement according to any one of claims 20 to 22, wherein the support carrier is at least a part of a cover housing in which the encapsulated circuit is mounted.

25. The circuit board arrangement according to any one of claims 20 to 22, wherein the support carrier is at least a part of an enclosure on which the encapsulated circuit board arrangement is mounted.

26. The circuit board arrangement according to any one of claims 20 to 22, wherein the support carrier is rigid.

27. The circuit board arrangement according to any one of claims 20 to 22, wherein the support carrier is bendable.

28. The circuit board arrangement according to claim 20, wherein at least one of the at least one sequentially processed layer comprises connection circuitry.

29. The circuit board arrangement according to any one of claims 20 or 28, wherein at least one of the at least one sequentially processed layer comprises tracks arranged as at least one passive component.

30. The circuit board arrangement according to any one of claims 20, 28 or 29, wherein at least one of the at least one sequentially processed layer comprises tracks arranged as at least one active component.

31. The circuit board arrangement according to 20, wherein the interface layer comprises at least one via.

32. The circuit board arrangement according to claim 31, wherein at least one of the at least one via is solid.

33. The circuit board arrangement according to any one of claims 20, 31 or 32, wherein the interface layer is bendable.

34. The circuit board arrangement according to any one of claims 20 or 32, wherein the interface layer is made of polymide.

35. A device comprising wireless communication means, wherein the device comprises an encapsulated circuit board arrangement according any one of claims 20 to 34.

36. A wireless mobile terminal, wherein the terminal comprises an encapsulated circuit board arrangement according any one of claims 20 to 34.
